(19) United States
(12) Patent Application Publication
(10) Pub. No.: US 2008/0079153 A1
(43) Pub. Date: Apr. 3, 2008

(54) METHOD FOR FORMING SEMICONDUCTOR DEVICE

(76) Inventor: Seong-Hee Jeong, Insimon (KR)

Correspondence Address: SHERR & NOURSE, PLLC, 620 HERNDON PARKWAY, SUITE 200, HERNDON, VA, 20170, US

(21) Appl. No.: 11/855,771

(22) Filed: Sep. 14, 2007

(30) Foreign Application Priority Data
Sep. 29, 2006 (KR) 10-2006-0095448

(51) Int. Cl. H01L 23/52; H01L 21/4763

(52) U.S. Cl. 257/741; 438/637; 257/E23.141; 257/E21.495

(57) ABSTRACT

A method for forming a semiconductor device including forming a metal layer over a semiconductor substrate; forming a nitride layer over the metal layer; performing a first etching process on the nitride layer; depositing an oxide layer over the nitride layer pattern and forming a photoresist pattern on the oxide layer; performing a second etching process using the photoresist pattern as an etching mask and etching the oxide layer; performing a third etching process on the nitride layer pattern until the metal layer is exposed, and forming a via-hole and a trench; and forming a metal wiring in the via-hole and the trench after removing the photoresist pattern.

The present application claims priority under 35 U.S.C. 119 to Korean Patent Application No. 10-2006-0095448 (filed on Sep. 29, 2006), which is hereby incorporated by reference in its entirety.

### BACKGROUND

Fabrication of semiconductor devices may require a damascene or dual-damascene process to form metal wiring. During the damascene or dual-damascene process, a via-hole may be formed in an interlayer insulation layer, or a via-hole or trench is formed in the interlayer insulation layer. A metal layer composed of copper may then be buried in the via-hole or in the via-hole and trench, and the metal layer may be planarized in order to form the metal wiring.

The dual-damascene process may be classified into a via-first method, a trench-first method, and a self-aligned method. In the via-first method, a photolithographic and etching process is performed on an insulation layer (i.e., a dielectric layer) in order to form a via-hole. Thereafter, an insulation layer is re-etched and a trench formed on and/or over the via-hole. The trench-first method is similar to the via-first method, however, the trench is formed prior to formation of the via-hole. The self-aligned dual-damascene method forms the via-hole and the trench in a single etching process by forming a primary pattern for the via-hole at a lower part of the damascene pattern, and forming a secondary pattern for the trench at an upper part of the damascene pattern using the insulation layer formed on the primary pattern. Thereafter, the etching process is performed using the secondary pattern as the etching mask. This etching process is continuously performed until the primary pattern is exposed, so that the trench is formed. This process is continuously executed using the primary pattern as an etching mask until the via-hole is formed. A copper seed layer may then be formed on inner walls of the trench and the via-hole.

The dual-damascene process has disadvantages such as the formation of a fence between the via-hole and the trench. Also, residual material and/or debris can remain in the via hole and trench if a nitride layer (SiN) is etched using reactive ion etching (RIE), creating a void in the via hole caused by fluorine.

### SUMMARY

Embodiments relate to a method for forming a semiconductor device which does not produce voids by eliminating foreign material and/or debris during formation of the via-hole and trench.

Embodiments relate to a method for forming a semiconductor device which prevents formation of fluorine-based materials during the etching process for forming the via-hole and trench.

Embodiments relate to a method for forming a semiconductor device that includes at least one of the following steps. Forming a metal layer on and/or over a semiconductor substrate. Forming a nitride layer on and/or over the metal layer. Forming a nitride layer pattern by selectively performing a first etching process on and/or over the nitride layer. Depositing an oxide layer on and/or over the nitride layer pattern and forming a photoresist pattern on and/or over the oxide layer. Performing a second etching process using the photoresist pattern as an etching mask and selectively etching the oxide layer. Performing a third etching process on and/or over the nitride layer pattern until the metal layer is exposed. Forming a via-hole and a trench. Forming a metal line in the via-hole and the trench after removing the photoresist pattern.

Embodiments relate to a semiconductor device that may include a semiconductor substrate; a metal layer formed on and/or over the semiconductor substrate; a nitride layer formed on and/or over the metal layer; an oxide layer formed on and/or over the nitride layer; a plurality of trenches and via holes formed in the nitride layer and the oxide layer; a seed layer formed in each of the plurality of trenches and via holes; a metal line formed over the seed layer inside each of the plurality trenches and via holes.

### DRAWINGS

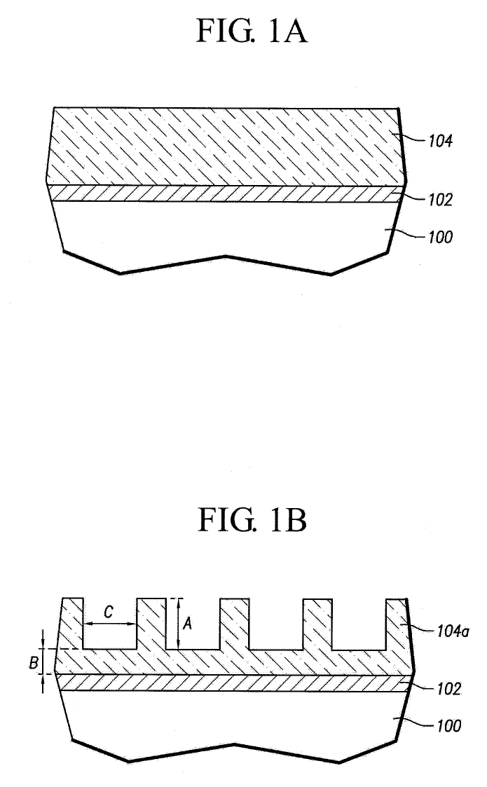

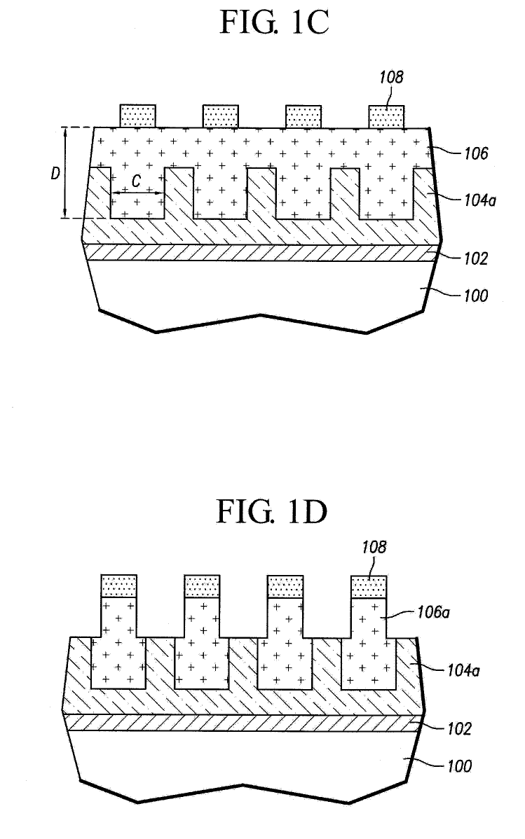

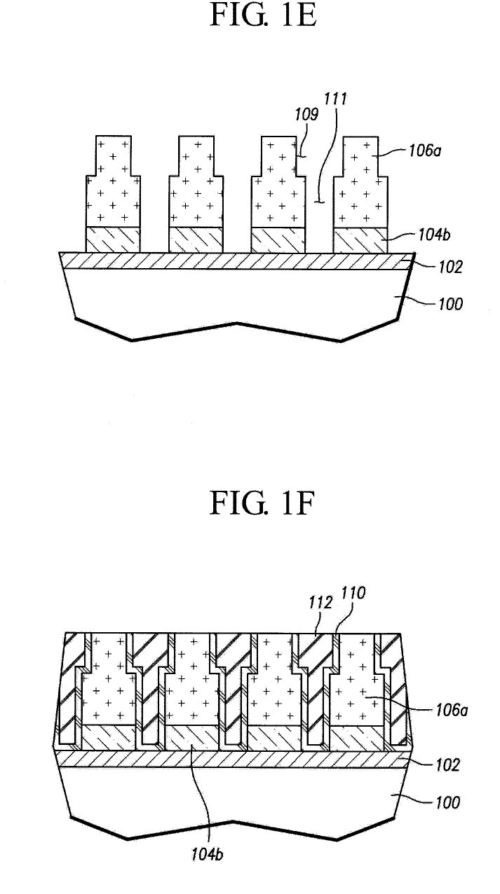

Example FIGS. 1A to 1F illustrate a method for forming a semiconductor device, in accordance with embodiments.

### DESCRIPTION

As illustrated in example FIG. 1A, metal layer 102 having a predetermined thickness can be formed on and/or over semiconductor substrate 100. Metal layer 102 may be composed of at least one of copper (Cu) and tungsten (W).

Nitride layer 104 having a predetermined thickness can be formed on and/or over metal layer 102. The nitride layer 104 can be formed by depositing a nitride material such as silicon nitride layer (e.g., Si₃N₄) on and/or over semiconductor substrate 100. Nitride layer 104 can have a thickness of between approximately 250 to 3500 Å as necessary. Nitride layer 104 may have a thickness of about 3000 Å.

As illustrated in example FIG. 1B, nitride layer 104 can be etched using a first etching process until its etched depth reaches a predetermined depth. Particularly, the first etching process for partially removing nitride layer 104 such that the etched depth “A” is about 2300 Å. The first etching process can produce a plurality of nitride layer patterns 104a having a predetermined gap “C” between each nitride layer pattern 104a. Nitride layer patterns 104a can have a concave-type shape.

The first etching process can have certain predetermined conditions, such as a power source of between approximately 1300 to 1800 W, bias power of between approximately 200 to 500 W, pressure of between approximately 20 to 50 MTorr, Ar in an amount of between approximately 280 to 420 sccm, CH₂F₂ in an amount of between approximately of 12.6 to 15.4 sccm, N₂ in an amount of between approximately 120 to 180 sccm, and O₂ in an amount of between approximately 8 to 12 sccm.

As illustrated in example FIG. 1C, oxide layer 106 having a predetermined thickness can be deposited on and/or over semiconductor substrate 100 and nitride layer pattern 104a. Oxide layer 106 may have a thickness “D” of about 5000 Å. Thereafter, a photoresist layer is patterned so that a plurality of photoresist patterns 108 can be formed on and/or over oxide layer 106.

A second etching process using photoresist patterns 108 as etching masks can then be performed. The second etching process can have certain predetermined conditions, such as a power source of between approximately 1100 to 1500 W, bias power of between approximately 1400 to 2000 W, pressure of between approximately 20 to 50 MTorr, C₅F₈ in an amount of between approximately 14 to 18 sccm, Ar in an amount of between approximately 600 to 1000 sccm, and O₂ in an amount of between approximately 13 to 17 sccm.

The width of each photoresist pattern 108 may be set relative to the predetermined spatial gap “C” between nitride layer patterns 104a. Consequently, the width of a trench may be determined relative to the width of each photoresist pattern 108, particularly, such that the width of the trench is less than the width of gap “C.”

As illustrated in example FIG. 1D, the second etching process can be performed until each nitride layer pattern 104a is exposed. Specifically, the second etching process can be conducted until the presence of cyanic (CN) gas is generated by the combination of C₅F₈ gas used during the second etching process and nitrogen (N) of nitride layer pattern 104a. Accordingly, if cyanic gas is detected during the second etching process, the second etching process can be halted so that a plurality of trenches 109 having a predetermined depth can be formed.

As illustrated in example FIG. 1E, each photoresist pattern 108 can be removed using an etching-cleaning process. Thereafter, each nitride layer pattern 104a can be selectively etched using a third etching process until metal layer 102 is exposed in order to form a plurality of via-holes 111. Each via-hole 111 can be formed simultaneously with the formation of second nitride layer patterns 104b. There are no impurities caused by photoresist patterns 108.

The third etching process condition can use the same predetermined conditions as the first etching process. In this way, the selection ratio of oxide layer 106 can be higher than that of nitride layer 104 by a predetermined value of about 15:1 so that oxide layer 106 is not etched.

As illustrated in example FIG. 1F, a plurality of copper seed layers 110 can be formed on inner walls of trenches 109 and via-holes 111. A metal layer can be buried in each trench 109 and via-hole 111 including copper seed layer 110, and the entire resultant surface of substrate 100 planarized using an etchback or chemical mechanical polishing (CMP) technique to form metal line 112.

In accordance with embodiments, a method of forming a semiconductor device can be advantageous for preventing the generation of a fence and/or any residual material left in the via-hole and the trench during formation of the via-hole and the trench are formed. Embodiments can also remove foreign material caused by the formation of the via-hole and trench, and thus, prevents formation of a void in the via-hole and trench. Embodiments can also prevent formation of any fluorine-based material during the etching process when forming the via-hole and trench, and thus, prevents formation of a void. Consequently, the overall production yield of the semiconductor may increase.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A method comprising:
forming a metal layer over a semiconductor substrate;
forming a nitride layer over the metal layer;
forming a nitride layer pattern by selectively performing a first etching process on the nitride layer;
forming an oxide layer over the nitride layer pattern;
forming a plurality of photoresist patterns on the oxide layer;
performing a second etching process using the plurality of photoresist patterns as an etching mask, and etching the oxide layer;
performing a third etching process on the nitride layer pattern until the metal layer is exposed and forming a via-hole and a trench; and
forming a metal line in the via-hole and the trench after removing the photoresist pattern.

2. The method of claim 1, wherein the second etching process is performed until cyanic gas is detected.

3. The method of claim 1, wherein the second etching process is performed until the nitride layer pattern is exposed.

4. The method of claim 1, wherein the step of forming the metal line in the via-hole and the trench includes:
forming a copper seed layer on inner walls of the via-hole and the trench;
burying a metal component in the via-hole and trench including the copper seed layer; and
planarizing the surface of the semiconductor substrate.

5. The method of claim 1, wherein the first etching process uses a power source of between approximately 1300 to 1800 W, bias power of between approximately 200 to 500 W, pressure of between approximately 20 to 50 MTorr, Ar in an amount of between approximately 280 to 420 sccm, CH₂F₂ in an amount of between approximately of 12.6 to 15.4 sccm, N₂ in an amount of between approximately 120 to 180 sccm, and O₂ in an amount of between approximately 8 to 12 sccm.

6. The method of claim 1, wherein the second etching process uses a power source of between approximately 1100 to 1500 W, bias power of between approximately 1400 to 2000 W, pressure of between approximately 20 to 50 MTorr, C₅F₈ in an amount of between approximately 14 to 18 sccm, Ar in an amount of between approximately 600 to 1000 sccm, and O₂ in an amount of between approximately 13 to 17 sccm.

7. The method of claim 1, wherein the nitride layer has a thickness of between approximately 2500 to 3500 Å.

8. The method of claim 1, wherein forming the nitride layer comprises depositing silicon nitride (Si₃N₄) over the metal layer.

9. The method of claim 1, wherein the nitride layer pattern has a depth of 2300 Å.

10. The method of claim 1, wherein the metal layer comprises at least one of copper and tungsten.

11. The method of claim 1, wherein the third etching process uses a power source of between approximately 1300 to 1800 W, bias power of between approximately 200 to 500 W, pressure of between approximately 20 to 50 MTorr, Ar in an amount of between approximately 280 to 420 sccm, CH₂F₂ in an amount of between approximately of 12.6 to 15.4 sccm, N₂ in an amount of between approximately 120 to 180 sccm, and O₂ in an amount of between approximately 8 to 12 sccm.

12. The method of claim 1, wherein the width of the photoresist pattern is less than the width of a gap between each nitride layer pattern.

13. The method of claim 12, wherein the trench has the same width as that of the photoresist pattern.

14. An apparatus comprising:
a semiconductor substrate;
a metal layer formed over the semiconductor substrate;
a nitride layer formed over the metal layer;
an oxide layer formed over the nitride layer;
a plurality of trenches and via holes formed in the nitride layer and the oxide layer;
a seed layer formed in each of the plurality of trenches and via holes;
a metal line formed over the seed layer inside each of the plurality trenches and via holes.

15. The apparatus of claim 14, wherein the metal layer comprises at least one of copper and tungsten.

16. The apparatus of claim 14, wherein the nitride layer comprises silicon nitride.

17. The apparatus of claim 16, wherein the silicon nitride layer has a thickness of between approximately 2500 to 3500 Å.

18. The apparatus of claim 16, wherein the silicon nitride layer has a thickness of about 3000 Å.

19. The apparatus of claim 14, wherein the seed layer comprises copper.

20. The apparatus of claim 14, wherein the oxide layer has a thickness of 5000 Å.
